(19) United States
(12) Patent Application Publication
(10) Pub. No.: US 2025/0024604 A1
(43) Pub. Date: Jan. 16, 2025

(54) SCREEN PROTECTOR

(71) Applicant: SANE PRODUCTS INC., Pasadena, CA (US)

(72) Inventors: Pei-Hsun LU, New Taipei City (TW); Wen Chi HSU, New Taipei City (TW)

(73) Assignee: SANE PRODUCTS INC., Pasadena, CA (US)

(21) Appl. No.: 18/771,724

(22) Filed: Jul. 12, 2024

Related U.S. Application Data
(60) Provisional application No. 63/526,547, filed on Jul. 13, 2023.

(51) Int. Cl. H05K 1/11; H04B 1/3888; H05K 1/02

(52) U.S. Cl. CPC H05K 1/118; H04B 1/3888; H05K 1/0298

(57) ABSTRACT

A screen protector including a body and a triggering protrusion. The body includes a first transparent substrate having a first inner surface and a first outer surface. The triggering protrusion includes a substrate, a first circuit layer, a micro switch, a conductive via and a second circuit layer. The substrate is bendably connected to a side edge of the first transparent substrate, and has a second inner surface and a second outer surface. The first circuit layer is disposed on the second outer surface. The micro switch is disposed on the second outer surface. The conductive via penetrates through the second inner surface and the second outer surface. The second circuit layer is disposed on the second inner surface and electrically connected to the first circuit layer via the at least one conductive via. The second circuit layer is electrically connected to the first transparent substrate.

### CROSS-REFERENCE TO RELATED APPLICATIONS

This non-provisional application claims priority under 35 U.S.C. § 119(a) on provisional Patent Application No(s). 63/526,547 filed in U.S.A. on Jul. 13, 2023 the entire contents of which are hereby incorporated by reference.

### TECHNICAL FIELD

The disclosure relates to a mobile phone accessory, more particularly to a screen protector.

### BACKGROUND

Recently, mobile games have become more and more popular due to the widespread use of the smartphones. In order to improve the user experience, some special types of screen protectors and phone cases have been developed to simulate the scenario for playing mobile games via a game controller. Specifically, there may be a button on the phone case to be cooperated with a micro switch disposed on a protrusion of the screen protector, and thus the touch screen of the smartphone is allowed to be triggered by the cooperation between the button and the micro switch.

However, the circuit layer is disposed on an outer surface of the protrusion of the screen protector. Thus, when the button is pressed and the protrusion is bent, the outer surface for disposing the circuit layer is in a convex shape. Accordingly, if the button is repeatedly pressed, a tension force will be repeatedly applied to the circuit layer, thereby causing the circuit layer to crack. In this way, the reliability for the screen protector to trigger the touch screen is reduced, and the lifespan of the screen protector is decreased.

### SUMMARY

The disclosure provides a screen protector having enhanced reliability for triggering the touch screen and increased lifespan.

One embodiment of this disclosure provides a screen protector including a body and a triggering protrusion. The body includes a first transparent substrate having a first inner surface and a first outer surface facing away from each other. The triggering protrusion includes a substrate, a first circuit layer, a micro switch, at least one conductive via and a second circuit layer. The substrate is bendably connected to a side edge of the first transparent substrate, and has a second inner surface and a second outer surface facing away from each other. The first inner surface is connected to the second inner surface. The first outer surface is connected to the second outer surface. The first circuit layer is disposed on the second outer surface. The micro switch is disposed on the second outer surface and electrically connected to the first circuit layer. The at least one conductive via penetrates through the second inner surface and the second outer surface. The second circuit layer is disposed on the second inner surface and electrically connected to the first circuit layer via the at least one conductive via. The second circuit layer is electrically connected to the first transparent substrate.

According to the screen protector disclosed by above embodiments, with the conductive via, the second circuit layer electrically connected to the first transparent substrate is allowed to be disposed on the second inner surface instead of the second outer surface. Thus, when the substrate of the triggering protrusion is bent relative to the first transparent substrate, comparing to being disposed on the second outer surface in a convex shape and enduring the tension force, the second circuit layer disposed on the second inner surface in a concave shape endures compression force. In this way, the second circuit layer is prevented from cracking. Accordingly, the reliability for the screen protector to trigger the touch screen is enhanced, and the lifespan of the screen protector is increased.

Moreover, since the second circuit layer is disposed on the second inner surface, the second circuit layer is hidden between the substrate and the smartphone during the usage of the screen protector. Thus, the oxidation and the abrasion of the second circuit layer are prevented, thereby further increasing the lifespan of the screen protector.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a side cross-sectional view showing a screen protector according to one embodiment of the disclosure and a smartphone; and

FIG. 2 is a partially enlarged view of the screen protector and the smartphone in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

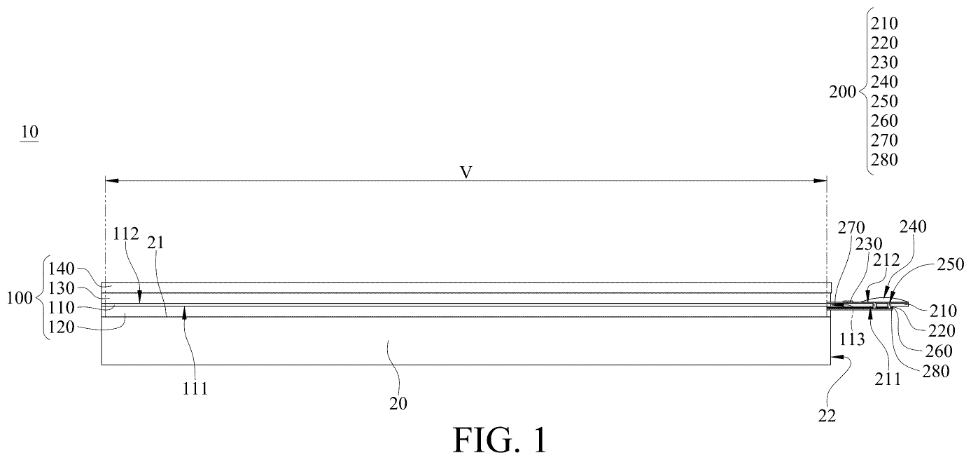

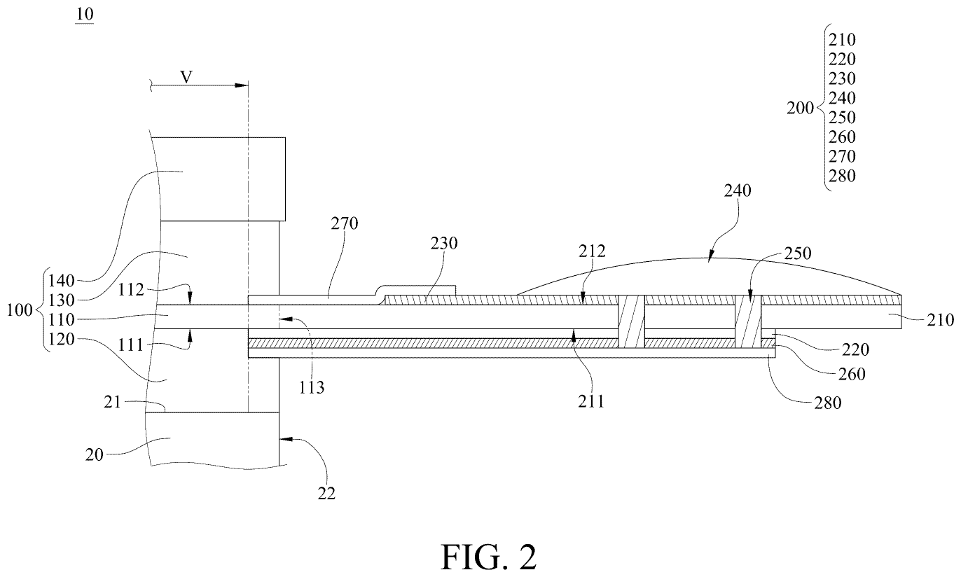

Please refer to FIGS. 1 and 2. FIG. 1 is a side cross-sectional view showing a screen protector 10 according to one embodiment of the disclosure and a smartphone 20. FIG. 2 is a partially enlarged view of the screen protector 10 and the smartphone 20 in FIG. 1. In this embodiment, the screen protector 10 includes a body 100 and at least one triggering protrusion 200. In other embodiments, the screen protector may include two or more triggering protrusions.

In this embodiment, the body 100 includes a first transparent substrate 110, a first adhesive layer 120, a second adhesive layer 130 and a second transparent substrate 140.

The first transparent substrate 110 is, for example, a polyethylene terephthalate (PET) substrate. The first transparent substrate 110 has a first inner surface 111 and a first outer surface 112 facing away from each other. In addition, the first transparent substrate 110 includes, for example, one or more circuit layers (not shown) disposed on the first inner surface 111 or the first outer surface 112.

The first adhesive layer 120 is disposed on the first inner surface 111 of the first transparent substrate 110. The first adhesive layer 120 is, for example, a conductive adhesive such as AB glue. The first adhesive layer 120 is configured to be adhered to a touch screen 21 of the smartphone 20. In some embodiments, the first adhesive layer 120 may be made of an electrostatic discharge material, thereby enhancing the reliability of the screen protector 10 in a dry environment.

The second adhesive layer 130 is disposed on the first outer surface 112 of the first transparent substrate 110. The second adhesive layer 130 is, for example, an optical clear adhesive (OCA).

The second transparent substrate 140 is disposed on the second adhesive layer 130. The second transparent substrate 140 is, for example, a glass substrate.

In this embodiment, the triggering protrusion 200 includes a substrate 210, a conductive film 220, a first circuit layer 230, a micro switch 240, a plurality of conductive vias 250, a second circuit layer 260, a first insulating layer 270 and a second insulating layer 280.

The substrate 210 is bendably connected to a side edge 113 of the first transparent substrate 110. The substrate 210 and the first transparent substrate 110 are, for example, integrally formed as a single piece. Thus, the substrate 210 and the first transparent substrate 110 are prevented from being separated from each other due to the crack therebetween, thereby enhancing the reliability of the screen protector 10. Note that for the purpose of explanation, the side edge 113 is defined on the position where the substrate 210 and the first transparent substrate 110 are connected. However, since the substrate 210 and the first transparent substrate 110 are, for example, integrally formed as a single piece, practically, there is no edge or boundary between the substrate 210 and the first transparent substrate 110.

The substrate 210 is made of, for example, Polyethylene terephthalate (PET). The substrate 210 has a second inner surface 211 and a second outer surface 212 facing away from each other. The second inner surface 211 is connected to the first inner surface 111. The second outer surface 212 is connected to the first outer surface 112.

The conductive film 220 and the first circuit layer 230 are disposed on the second inner surface 211 and the second outer surface 212, respectively. The conductive film 220 is made of, for example, Indium Tin Oxide (ITO).

The micro switch 240 is disposed on the first circuit layer 230. In some embodiments, there may be a protective layer disposed between the first circuit layer 230 and the micro switch 240. The said protective layer may be conductive and made of, for example, carbon. Thus, the said protective layer may prevent the oxidation or abrasion of the first circuit layer 230 while maintaining the electrical connection between the first circuit layer 230 and the micro switch 240.

The conductive via 250 is located in the substrate 210 and the conductive film 220. That is, a part of the conductive via 250 is located in the substrate 210, and another part of the conductive via 250 is located in the conductive film 220. In addition, the conductive via 250 penetrates through the second inner surface 211 and the second outer surface 212.

The second circuit layer 260 is disposed on the conductive film 220, and is electrically connected to the first circuit layer 230 via the conductive vias 250. Furthermore, in this embodiment, the second circuit layer 260 is electrically connected to the circuit layer(s) of the first transparent substrate 110 via the conductive film 220, but the disclosure is not limited thereto. In other embodiments, the triggering protrusion may not include the conductive film 220, and the second circuit layer may be electrically connected to the circuit layer(s) of the first transparent substrate directly.

In this embodiment, a part of the conductive film 220 and a part of the second circuit layer 260 are located on, for example, a position where the first transparent substrate 110 and the substrate 210 are connected. That is, when the substrate 210 is bent relative to the first transparent substrate 110, the conductive film 220 and the second circuit layer 260 are located on a bent edge between the substrate 210 and the first transparent substrate 110.

The first circuit layer 230, the second circuit layer 260 and the conductive vias 250 are made of, for example, a metal having excellent conductivity, such as silver, copper and gold.

The first insulating layer 270 is disposed on the first circuit layer 230. The second insulating layer 280 is disposed on the second circuit layer 260. The first insulating layer 270 and the second insulating layer 280 prevent the oxidation of the first circuit layer 230 and the second circuit layer 260, and prevent the first circuit layer 230 and the second circuit layer 260 from unnecessarily contacting other components. Thus, the false triggering on the first circuit layer 230 and the second circuit layer 260 and the abrasion thereof are prevented, thereby further enhancing the reliability of the screen protector 10 and increasing the lifespan of the screen protector 10. In addition, the first insulating layer 270 and the second insulating layer 280 cover the first circuit layer 230 and the second circuit layer 260 to improve the appearance of the screen protector 10. In other embodiments, the triggering protrusion may not include the first insulating layer 270 and the second insulating layer 280.

In this embodiment, a part of the conductive film 220, a part of the second circuit layer 260, and a part of the second insulating layer 280 are located in the first adhesive layer 120. That is, the conductive film 220, the second circuit layer 260 and the second insulating layer 280, for example, extend into the first adhesive layer 120. Specifically, the conductive film 220, the second circuit layer 260 and the second insulating layer 280 extend to, for example, an edge of a viewing area V (or may be referred as a visible area) of the touch screen 21. Thus, the overlapped area between the second circuit layer 260 and the conductive film 220 is enlarged, thereby reducing the resistance for signals to be transferred therebetween. However, in other embodiments, the conductive film, the second circuit layer and the second insulating layer may extend to the side edge of the first adhesive layer (i.e., may be flushed or aligned with the side edge of the first adhesive layer), or may be located outside the first adhesive layer while being spaced apart from the side edge of the first adhesive layer.

In this embodiment, a part of the first insulating layer 270 is located in the second adhesive layer 130. That is, the first insulating layer 270 extends into the second adhesive layer 130. However, the disclosure is not limited thereto. In other embodiments, the first insulating layer may extend to the side edge of the second adhesive layer (i.e., may be flushed or aligned with the side edge of the second adhesive layer), or may be located outside the second adhesive layer while being spaced apart from the side edge of the second adhesive layer.

The screen protector 10 of this disclosure may be cooperated with a phone case (not shown). There is an opening on a sidewall of the phone case. The triggering protrusion 200 may be bent relative to the body 100 and adhered to, for example, a side surface 22 of the smartphone 20 after being bent. Also, a trigger such as a button may be disposed in the opening and rest on the micro switch 240 of the triggering protrusion 200. The trigger may be flushed with an outer surface of the sidewall or protrude out of the outer surface of the sidewall.

When the trigger is pressed, the micro switch 240 is triggered, and thus the touch screen 21 of the smartphone 20 is triggered via the first circuit layer 230, the conductive vias 250, the second circuit layer 260, the conductive film 220, the circuit layer(s) in the first transparent substrate 110 and the first adhesive layer 120.

According to the screen protector disclosed by above embodiments, with the conductive via, the second circuit layer electrically connected to the first transparent substrate is allowed to be disposed on the second inner surface instead of the second outer surface. Thus, when the substrate of the triggering protrusion is bent relative to the first transparent substrate, comparing to being disposed on the second outer surface in a convex shape and enduring the tension force, the second circuit layer disposed on the second inner surface in a concave shape endures compression force. In this way, the second circuit layer is prevented from cracking. Accordingly, the reliability for the screen protector to trigger the touch screen is enhanced, and the lifespan of the screen protector is increased.

Moreover, since the second circuit layer is disposed on the second inner surface, the second circuit layer is hidden between the substrate and the smartphone during the usage of the screen protector. Thus, the oxidation and the abrasion of the second circuit layer are prevented, thereby further increasing the lifespan of the screen protector.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A screen protector, comprising:
a body, comprising a first transparent substrate having a first inner surface and a first outer surface facing away from each other; and
a triggering protrusion, comprising:
a substrate, bendably connected to a side edge of the first transparent substrate and having a second inner surface and a second outer surface facing away from each other, wherein the first inner surface is connected to the second inner surface, and the first outer surface is connected to the second outer surface;
a first circuit layer, disposed on the second outer surface;
a micro switch, disposed on the second outer surface and electrically connected to the first circuit layer;
at least one conductive via, penetrating through the second inner surface and the second outer surface; and
a second circuit layer, disposed on the second inner surface and electrically connected to the first circuit layer via the at least one conductive via, wherein the second circuit layer is electrically connected to the first transparent substrate.

2. The screen protector according to claim 1, wherein a part of the second circuit layer is located on a position where the first transparent substrate and the substrate of the triggering protrusion are connected.

3. The screen protector according to claim 1, wherein the triggering protrusion further comprises a conductive film, the conductive film is disposed on the second inner surface of the substrate, and the second circuit layer is electrically connected to the first transparent substrate via the conductive film.

4. The screen protector according to claim 3, wherein a part of the conductive film is located on a position where the first transparent substrate and the substrate of the triggering protrusion are connected.

5. The screen protector according to claim 3, wherein the second circuit layer is disposed on the conductive film, and a part of the at least one conductive via is located in the conductive film.

6. The screen protector according to claim 3, wherein the body further comprises a first adhesive layer, a second adhesive layer and a second transparent substrate, the first adhesive layer is disposed on the first inner surface, the second adhesive layer is disposed on the first outer surface, and the second transparent substrate is disposed on the second adhesive layer.

7. The screen protector according to claim 6, wherein a part of the conductive film and a part of the second circuit layer are located in the first adhesive layer.

8. The screen protector according to claim 1, wherein the triggering protrusion further comprises a first insulating layer and a second insulating layer, the first insulating layer is disposed on the first circuit layer, and the second insulating layer is disposed on the second circuit layer.

9. The screen protector according to claim 1, wherein the substrate and the first transparent substrate are integrally formed as a single piece.

10. The screen protector according to claim 1, wherein the first circuit layer, the at least one conductive via and the second circuit layer are made of silver, copper or gold.
